(19) United States
(12) Patent Application Publication
(10) Pub. No.: US 2008/0017927 A1
(43) Pub. Date: Jan. 24, 2008

(54) Semiconductor device and fabrication method thereof

(76) Inventor: Hiroshi Ohkawa, Hyogo (JP)

Correspondence Address: MCDERMOTT WILL & EMERY LLP, 600 13TH STREET, NW, WASHINGTON, DC, 20005-3096, US

(21) Appl. No.: 11/806,883

(22) Filed: Jun. 5, 2007

(30) Foreign Application Priority Data
Jul. 20, 2006 (JP) 2006-198391

(51) Int. Cl. H01L 29/49; H01L 21/3205

(52) U.S. Cl. 257/365; 438/587; 438/588; 257/E29.139; 257/E21.295

(57) ABSTRACT

A semiconductor device includes a dual gate electrode lying across the tops of a first element region and a second element region formed apart from each other with an isolation region interposed between the first and second element regions. The dual gate electrode is composed of two silicide regions with different compositions: a first silicide region on top of the first element region and a second silicide region on top of the second element region. The interface between the first and second silicide regions includes a tilted plane.

### BACKGROUND OF THE INVENTION

(a) Field of the Invention

This invention relates to a semiconductor device with a dual gate electrode capable of providing stable electric properties and a method for fabricating the same.

(b) Description of the Related Art

In order to meet the recent demand for higher packing density and higher operation speed of semiconductor integrated circuits, metal alloys or high-melting point metal alloys have been employed for gate electrode wirings. Further, in order to provide a semiconductor device including an N-type MIS transistor and a P-type MIS transistor both having a low threshold voltage, a so-called dual gate electrode structure has been recently employed in which the gate electrode regions for N-type and P-type MIS transistors are formed from different materials of different work functions. For example, there is known a method for forming a dual gate electrode on N-type and P-type MIS transistors from different silicide materials having different compositions (see J. A. Kittl et al., “Scalability of Ni FUSI gate processes: phase and Vt control to 30 nm gate lengths”, 2005 Symposium on VLSI Technology Digest of Technical Papers, 2005, pp. 72-73).

FIG. 12 is a plan view schematically showing a dual gate electrode structure. As shown in the figure, a dual gate electrode 120 is formed across the top of an element region 101A having an N-type MIS transistor formed therein and the top of an element region 101B having a P-type MIS transistor formed therein.

A description is given of a known method for fabricating a semiconductor device including a dual gate electrode with reference to FIGS. 13A to 13E and FIGS. 14A to 14E. FIGS. 13A to 13E are cross-sectional views taken along the line XIII-XIII of FIG. 12 and showing process steps of the fabrication method when a semiconductor device is viewed in a direction of the gate width, and FIGS. 14A to 14E are cross-sectional views taken along the line XIVa-XIVa and the line XIVb-XIVb of FIG. 12 and showing process steps of the fabrication method when the semiconductor device is viewed in a direction of the gate length.

First, as shown in FIGS. 13A and 14A, an isolation region 112 is formed in a semiconductor substrate 111 of silicon by shallow trench isolation (STI) to isolate an N-type MIS transistor forming region A (hereinafter, referred to as a region A) from a P-type MIS transistor forming region B (hereinafter, referred to as a region B). Thereafter, a gate insulating film 113 of silicon dioxide or a hafnium oxide is formed on the semiconductor substrate 111 and a polycrystalline silicon film 114 and a silicon dioxide film 115 are then formed in this order on the semiconductor substrate 111.

Next, as shown in FIGS. 13B and 14B, the silicon dioxide film 115, the polycrystalline silicon film 114 and the gate insulating film 113 are sequentially etched by photolithography or reactive ion etching (RIE) to pattern the polycrystalline silicon film 114 into the shape of a gate electrode. Thereafter, extension regions 121 and pocket regions (not shown) are formed in both the regions A and B of the semiconductor substrate 111, sidewalls 116 are then formed on the sides of the patterned polycrystalline silicon film 114 and source/drain regions 122 are then formed in both the regions A and B.

Thereafter, the semiconductor substrate 111 is thermally treated to activate impurities implanted into the semiconductor substrate 111 and the polycrystalline silicon film 114 and only the top surfaces of the source/drain regions 122 are silicided to form silicide regions 123. Subsequently, an interlayer film 117 of silicon dioxide is deposited on the layer stack, then thinned by chemical mechanical polishing (CMP) or RIE until exposure of the silicon dioxide film 115 and then completely removed by wet etching or RIE.

Next, as shown in FIGS. 13C and 14C, a resist film 118 is formed on the polycrystalline silicon film 114 to cover the region A and expose the region B. Subsequently, the surface of the polycrystalline silicon film 114 is etched using the resist film 118 as a mask to make the thickness of a portion of the polycrystalline silicon film 114 on the region B thinner than that of a portion of the polycrystalline silicon film 114 on the region A.

Next, as shown in FIGS. 13D and 14D, the resist film 118 is removed, a nickel (Ni) film 119 is then deposited on the polycrystalline silicon film 114 and the semiconductor substrate 111 is then thermally treated to induce silicidation reaction between the polycrystalline silicon film 114 and the Ni film 119. Thereafter, an unreacted part of the Ni film 119 is selectively removed and the semiconductor substrate 111 is then additionally thermally treated to form, as shown in FIGS. 13E and 14E, a NiSi film 120A and a Ni₃Si film (or Ni₃₁Si₁₂ film) 120B on the regions A and B, respectively. The induction of the two-step silicidation reaction as described above provides complete silicidation of the Ni film 119 on the polycrystalline silicon film 114. As a result, a fully silicided gate electrode made of the NiSi film 120A is formed on the N-type MIS transistor forming region A and a fully silicided gate electrode made of the Ni₃Si film (or Ni₃₁Si₁₂ film) 120B is formed on the P-type MIS transistor forming region B.

### SUMMARY OF THE INVENTION

In the known technique, in order to form two different silicide films having different compositions, one on the N-type MIS transistor forming region A and the other on the P-type MIS transistor forming region B, the polycrystalline silicon film must have a stepped part at the boundary between both the regions A and B. According to the known technique, portions of the silicide films formed at flat parts of the polycrystalline silicon film have their respective constant compositions based on their respective thickness ratios between the polycrystalline silicon film and the overlying metal film. On the other hand, the stepped part of the polycrystalline silicon film is supplied with not only metal from a part of the metal film overlying it but also surplus metal from a part of the metal film adjoining its shoulder (its side face). Thus, the interface between the silicide films having different compositions is laterally offset from the stepped part of the polycrystalline silicon film. Specifically, the interface between the NiSi film 120A and the Ni₃Si film 120B as shown in FIG. 13E is formed offset from the stepped part of the polycrystalline silicon film 114 as shown in FIG. 13D towards the N-type MIS transistor forming region A.

Even if the interface is offset from the stepped part of the polycrystalline silicon film, there is no problem so long as it is on the isolation region 112. However, if the interface reaches the N-type MIS transistor forming region A, the electric properties of the N-type MIS transistor, such as the threshold voltage, might vary, thereby providing unstable transistor characteristics and in turn deteriorating the transistor reliability.

To avoid malfunction, large-capacity SRAMs, for example, must satisfy severe requirements in regard to variations in transistor characteristics (e.g., a requirement of a variation in drive current Id of 2% or less). If variations in transistor characteristics of an SRAM owing to an offset of the interface are problematic, this creates a need to increase the width of the isolation region, which prevents miniaturization of the SRAM.

The present invention has been made in view of the foregoing points and, therefore, its principal object is to provide a semiconductor device including a dual gate electrode having stable transistor characteristics even when miniaturized and also provide a method for fabricating the semiconductor device.

To attain the above object, a semiconductor device according to the present invention employs a dual gate electrode structure in which the interface between two silicide films having different compositions includes a tilted plane. Thus, the amount of surplus metal supplied from the part of the metal film adjoining a tilted shoulder of the stepped part of the polycrystalline silicon film can be less than the amount of surplus metal supplied from the vertical shoulder of the stepped part in the known technique. As a result, the amount of offset of the interface between the silicide films of different compositions can be reduced to less than that in the known technique. This prevents variations in transistor characteristics due to offset of the interface and in turn provides a semiconductor device including a dual gate electrode having stable transistor characteristics even when miniaturized.

Specifically, a first aspect of the present invention is directed to a semiconductor device including a dual gate electrode lying across the tops of a first element region and a second element region formed apart from each other with an isolation region interposed between the first and second element regions. In the semiconductor device, the dual gate electrode is composed of a first silicide region and a second silicide region having different compositions, the first and second silicide region lie on top of the first and second element regions, respectively, and the interface between the first and second silicide regions includes a plane tilted from lower to higher positions in a direction of thickness of the dual gate electrode.

With the above configuration, variations in transistor characteristics due to offset of the interface can be prevented, which provides a semiconductor device including a dual gate electrode having stable transistor characteristics even when miniaturized.

In a preferred embodiment, the first and second silicide regions comprise regions formed by siliciding first and second regions of different thicknesses of a polycrystalline silicon film, a stepped part of the polycrystalline silicon film between the first and second regions is formed to have a tilt, and the position of the interface substantially corresponds to the position of the stepped part.

With the above configuration, a tilted plane can be easily formed in the interface between the silicide films by siliciding the polycrystalline silicon film having a tilt.

In a preferred embodiments the position of the interface between the first and second silicide regions at the bottom of the dual gate electrode is on the isolation region.

The position of the interface at the bottom of the dual gate electrode is preferably on the isolation region and closer to the second element region than the first element region.

Furthermore, the interface is preferably tilted beginning with the bottom of the dual gate electrode and from near the second element region towards the first element region.

Preferably, the first element region is an N-type MIS transistor forming region, the second element region is a P-type MIS transistor forming region, the first silicide region is composed of a NiSi film, and the second silicide region is composed of a Ni₃Si film or a Ni₃₁Si₁₂ film.

A second aspect of the present invention is directed to a method for fabricating a semiconductor device. The method includes the steps of: (a) forming a first element region and a second element region apart from each other with an isolation region interposed between the first and second element regions; (b) forming a polycrystalline silicon film on the first and second element regions with a gate insulating film formed between the polycrystalline silicon film and both the first and second element regions; (c) selectively etching the surface of the polycrystalline silicon film to form, in the polycrystalline silicon film, a first region on the first element region, a second region on the second element region and a boundary region between the first and second regions, the second region being thinner than the first region, the boundary region including a tilted shoulder; (d) forming a metal film over the first region, the boundary region and the second region of the polycrystalline silicon film; and (e) inducing silicidation reaction between the polycrystalline silicon film and the metal film to form a first silicide region and a second silicide region with different compositions, the first silicide region being formed by fully siliciding the first region of the polycrystalline silicon film, the second silicide region being formed by fully siliciding the second region of the polycrystalline silicon film, wherein the step (e) includes fully siliciding the boundary region of the polycrystalline silicon film while forming the first and second silicide regions and the interface between the first and second silicide regions includes a plane tilted from lower to higher positions in a direction of thickness of the dual gate electrode.

In a preferred embodiment, the first and second silicide regions forms a dual gate electrode lying across the tops of the first and second element regions.

In a preferred embodiment, the method further includes the step (f) of patterning the polycrystalline silicon film into a gate electrode after the step (b) and before the step (c), wherein the step (c) includes the steps of: (c1) forming a resist film on the patterned polycrystalline silicon film to cover the first element region and expose the second element region; and (c2) etching part of the polycrystalline silicon film located on the second element region with the resist film as a mask, thereby forming the second region of the polycrystalline silicon film and forming the tilted shoulder in the boundary region.

In another preferred embodiment, the method further includes the step (f) of patterning the polycrystalline silicon film into a gate electrode after the step (c) and before the step (d), wherein the step (c) includes the steps of: (c1) forming a resist film on the polycrystalline silicon film to cover the first element region and expose the second element region; and (c2) etching part of the polycrystalline silicon film located on the second element region with the resist film as a mask, thereby forming the second region of the polycrystalline silicon film and forming the tilted shoulder in the boundary region.

A third aspect of the present invention is also directed to a method for fabricating a semiconductor device. The method includes the steps of: (a) forming a first element region and a second element region apart from each other with an isolation region interposed between the first and second element regions; (b) forming a polycrystalline silicon film on the first and second element regions with a gate insulating film formed between the polycrystalline silicon film and both the first and second element regions; (c) selectively etching the surface of the polycrystalline silicon film to form, in the polycrystalline silicon film, a first region on the first element region a second region on the second element region and a boundary region between the first and second regions, the second region being thinner than the first region, the boundary region including a stepped part; (d) forming an anti-silicidation film on the side face of the stepped part in the boundary region of the polycrystalline silicon film; (e) patterning the polycrystalline silicon film into a gate electrode after the step (d); (f) forming a metal film over the polycrystalline silicon film and the anti-silicidation film after the step (e); and (g) inducing silicidation reaction between the polycrystalline silicon film and the metal film to form a first silicide region and a second silicide region with different compositions, the first silicide region being formed by fully siliciding the first region of the polycrystalline silicon film, the second silicide region being formed by fully siliciding the second region of the polycrystalline silicon film, wherein the step (g) includes fully siliciding the boundary region of the polycrystalline silicon film with the anti-silicidation film as a mask while forming the first and second silicide regions.

In a preferred embodiment, the first and second silicide regions forms a dual gate electrode lying across the tops of the first and second element regions.

### BRIEF DESCRIPTION OF THE DRAWINGS

FIG. 1 is a plan view schematically showing the configuration of a semiconductor device according to a first embodiment of the present invention.

FIGS. 2A to 2E are cross-sectional views schematically showing process steps of a method for fabricating a semiconductor device according to the first embodiment.

FIGS. 3A to 3E are cross-sectional views schematically showing the process steps of the method for fabricating a semiconductor device according to the first embodiment.

FIGS. 4A to 4D are cross-sectional views schematically showing process steps of a method for fabricating a semiconductor device according to a second embodiment of the present invention.

FIGS. 5A to 5B are cross-sectional views schematically showing process steps of the method for fabricating a semiconductor device according to the second embodiment.

FIGS. 6A to 6D are cross-sectional views schematically showing process steps of the method for fabricating a semiconductor device according to the second embodiment.

FIGS. 7A to 7B are cross-sectional views schematically showing process steps of the method for fabricating a semiconductor device according to the second embodiment.

FIGS. 8A to 8E are cross-sectional views schematically showing process steps of a method for fabricating a semiconductor device according to a third embodiment of the present invention.

FIGS. 9A to 9B are cross-sectional views schematically showing process steps of the method for fabricating a semiconductor device according to the third embodiment.

FIGS. 10A to 10E are cross-sectional views schematically showing process steps of the method for fabricating a semiconductor device according to the third embodiment.

FIGS. 11A to 11B are cross-sectional views schematically showing process steps of the method for fabricating a semiconductor device according to the third embodiment.

FIG. 12 is a plan view schematically showing the configuration of a known semiconductor device.

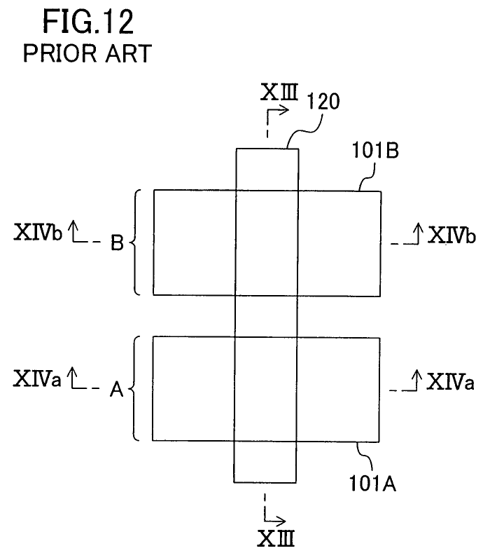

FIGS. 13A to 13E are cross-sectional views schematically showing process steps of a known method for fabricating a semiconductor device.

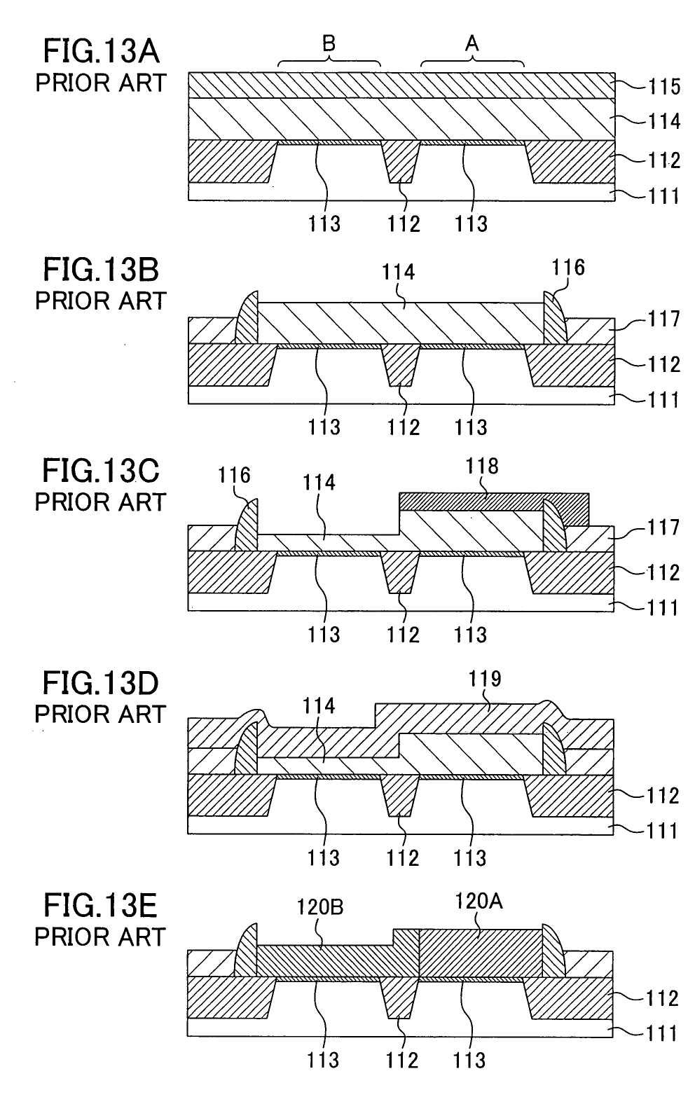

FIGS. 14A to 14E are cross-sectional views schematically showing the process steps of the known method for fabricating a semiconductor device.

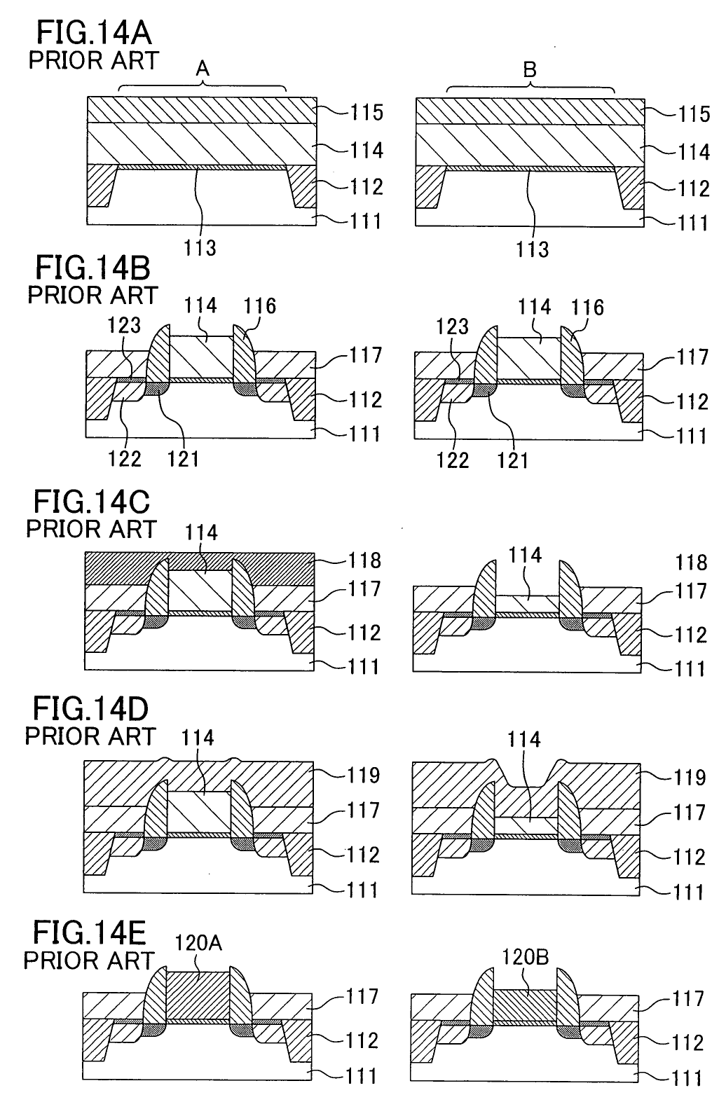

### DETAILED DESCRIPTION OF THE PREFERRED EMBODIMENTS

A description is given below of embodiments of the present invention with reference to the drawings. For simplicity of explanation, elements with substantially the same functions are identified by the same reference numerals. Note that the present invention is not limited to the following embodiments.

### Embodiment 1

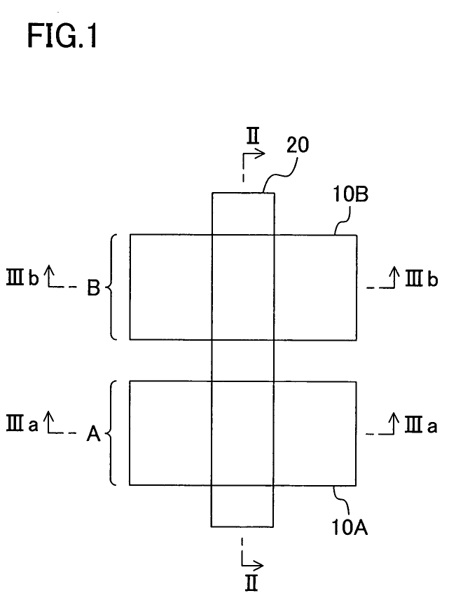

FIG. 1 is a plan view schematically showing the configuration of a semiconductor device according to a first embodiment of the present invention. As shown in the figure, a dual gate electrode 20 is formed across the top of a first element region 10A having an N-type MIS transistor formed therein and the top of a second element region 10B having a P-type MIS transistor formed therein.

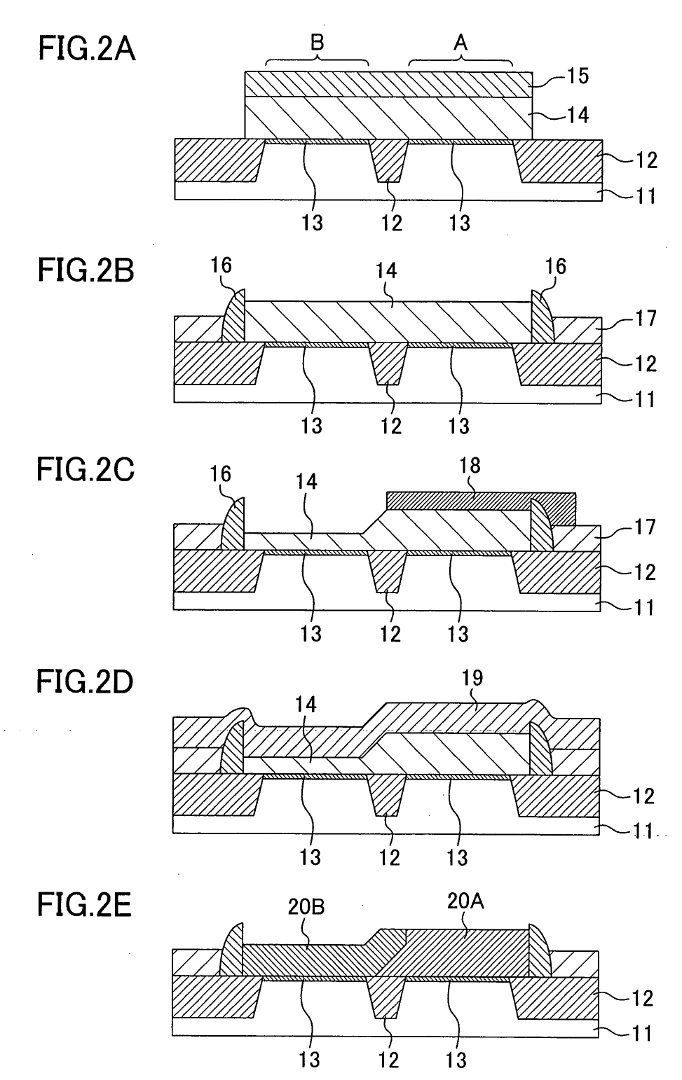

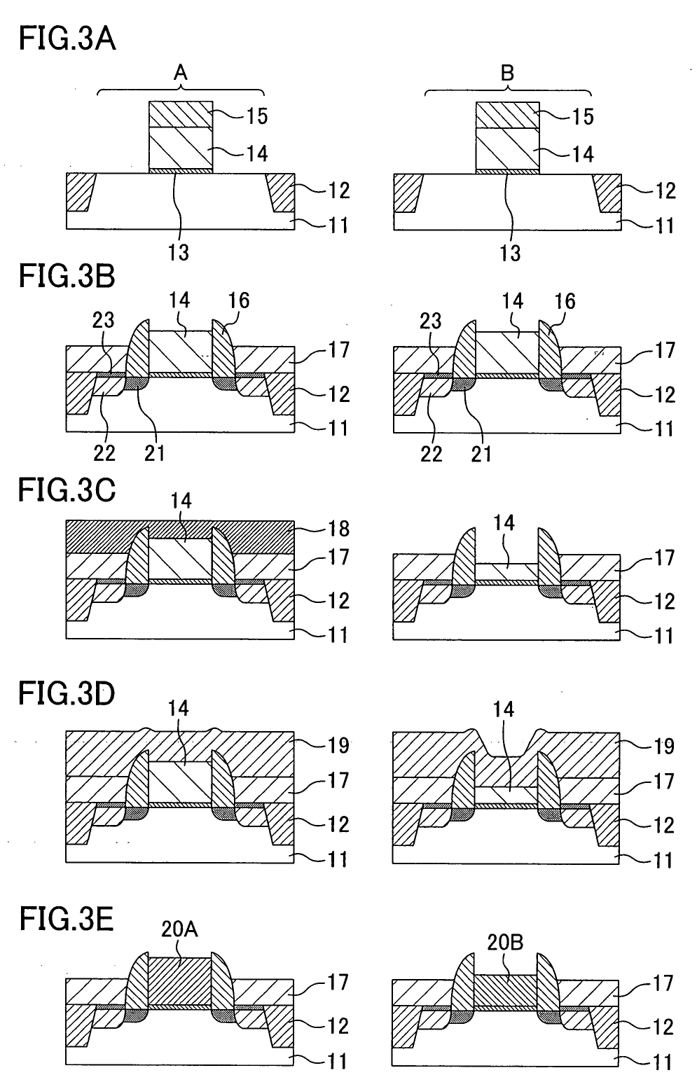

FIGS. 2A to 2E and FIGS. 3A to 3E are cross-sectional views schematically showing process steps of a method for fabricating a semiconductor device according to this embodiment, wherein FIGS. 2A to 2E are cross-sectional views taken along the line II-II of FIG. 1 and showing process steps when viewed in a direction of the gate width and FIGS. 3A to 3E are cross-sectional views taken along the line IIIa-IIIa and the line IIIb-IIIb of FIG. 1 and showing the process steps when viewed in a direction of the gate length.

The following description is given of the method for fabricating a semiconductor device according to this embodiment with reference to FIGS. 2A to 2E and FIGS. 3A to 3E.

First, as shown in FIGS. 2A and 3A, an isolation region 12 is formed in a semiconductor substrate 11 of silicon by STI to isolate an N-type MIS transistor forming region A (hereinafter, referred to as a region A) from a P-type MIS transistor forming region B (hereinafter, referred to as a region B). Thereafter, a 2 to 4 nm thick gate insulating film 13 made of silicon dioxide or a hafnium oxide is formed on the semiconductor substrate 11 and a 100 nm thick polycrystalline silicon film 14 and a 60 nm thick silicon dioxide film 15 are then formed in this order on the semiconductor substrate 11 (on the gate insulating film 13). Subsequently, the silicon dioxide film 15, the polycrystalline silicon film 14 and the gate insulating film 13 are sequentially etched by photolithography or RIE to pattern the polycrystalline silicon film 14 into the shape of a gate electrode.

Next, as shown in FIGS. 2B and 3B, extension regions 21 and pocket regions (not shown) are formed in both the regions A and B of the semiconductor substrate 11, sidewalls 16 are then formed on the sides of the patterned polycrystalline silicon film 14 and source/drain regions 22 are then formed in both the regions A and B. Thereafter, the semiconductor substrate 11 is thermally treated to activate impurities implanted into the semiconductor substrate 11 and the polycrystalline silicon film 14 and only the top surfaces of the source/drain regions 22 of the semiconductor substrate 11 are silicided to form silicide regions 23. Subsequently, an interlayer film 17 of silicon dioxide is deposited on the layer stack, then thinned by CMP or RIE until exposure of the silicon dioxide film 15 and then completely removed by wet etching or RIE.

Next, as shown in FIGS. 2C and 3C, a resist film 18 is formed on the polycrystalline silicon film 14 to cover the region A and expose the region B. Thereafter, the exposed portion of the polycrystalline silicon film 14 is etched about a thickness of 60 nm by RIE using the resist film 18 as a mask to thin that portion of the polycrystalline silicon film 14 on the region B down to about 40 nm.

The etching is performed under a condition where the selective etching ratio of the resist film 18 to the polycrystalline silicon film 14 is substantially 1 to 1. Thus, and since the etching progresses while gradually reducing the surface level of the resist film 18, the polycrystalline silicon film 14 after the end of the etching is formed with a stepped part having a tilted shoulder (forward tapered shoulder) as shown in FIG. 2C. The etching may be implemented by wet etching. In this case, the resist film 18 is preferably formed so that its relevant end can be offset towards the region B by about an amount of film etched away more than that by RIE.

Next, as shown in FIGS. 2D and 3D, a nickel (Ni) film 19 is then deposited with a thickness of about 70 nm on the polycrystalline silicon film 14 and the semiconductor substrate 11 is then thermally treated at about 350° C. for about 30 seconds to induce silicidation reaction between the polycrystalline silicon film 14 and the Ni film 19.

Thereafter, an unreacted part of the Ni film 19 is selectively removed and the semiconductor substrate 11 is then additionally thermally treated at about 520° C. for about 30 seconds. Thus, as shown in FIGS. 2E and 3E, a NiSi film 20A and a Ni₃Si film (or Ni₃₁Si₁₂ film) 20B are formed on the regions A and B, respectively. The induction of the two-step silicidation reaction provides complete silicidation of the Ni film 19 on the polycrystalline silicon film 14. As a result, a fully silicided gate electrode made of the NiSi film 20A is formed on the N-type MIS transistor forming region A and a fully silicided gate electrode made of the Ni₃Si film (or Ni₃₁Si₁₂ film) 20B is formed on the P-type MIS transistor forming region B. In this case, the first and second silicide regions 20A and 20B are formed so that the position of their interface at the bottom of their thickness can be on the isolation region 12 and near the region B and the position thereof at the top of their thickness can be directly above the isolation region 12 and near the region A or directly above the region A.

The semiconductor device obtained by the above fabrication method includes a dual gate electrode 20 lying across the tops of both of a first element region (N-type MIS transistor region) 10A and a second element region (P-type MIS transistor region) 10B formed apart from each other with the isolation region 12 interposed therebetween. The dual gate electrode 20 is composed of two silicide regions with different compositions: a first silicide region (NiSi film) 20A on the first element region 10A and a second silicide region (Ni₃Si film or Ni₃₁Si₁₂ film) 20B on the second element region 10B. The interface between the first and second silicide regions 20A and 20B includes a tilted plane.

Specifically, the first and second silicide regions 20A and 20B are constituted by different regions formed by siliciding first and second regions of different thicknesses of the polycrystalline silicon film 14. The stepped part between the first and second regions of the polycrystalline silicon film 14 is formed to have a tilted shoulder. The position of the interface between the first and second silicide regions 20A and 20B substantially corresponds to the position of the stepped part between the first and second regions of the polycrystalline silicon film 14.

The position to form the stepped part between the first and second regions of the polycrystalline silicon film 14 is preferably determined in advance so that the interface between the first and second silicide regions 20A and 20B can be located on the isolation region 12.

According to this embodiment, since the dual gate electrode is formed to have a tilted plane between silicide films 20A and 20B of different compositions as described above, the amount of surplus metal supplied from the part of the metal film (Ni film) 19 adjoining the tilted shoulder of the stepped part of the polycrystalline silicon film 14 can be less than the amount of surplus metal supplied from the vertical shoulder of the stepped part in the known technique. As a result, the amount of offset of the interface between the silicide films 20A and 20B can be reduced to less than that in the known technique. This prevents variations in transistor characteristics due to offset of the interface and in turn provides a semiconductor device including a dual gate electrode having stable transistor characteristics even when miniaturized.

### Embodiment 2

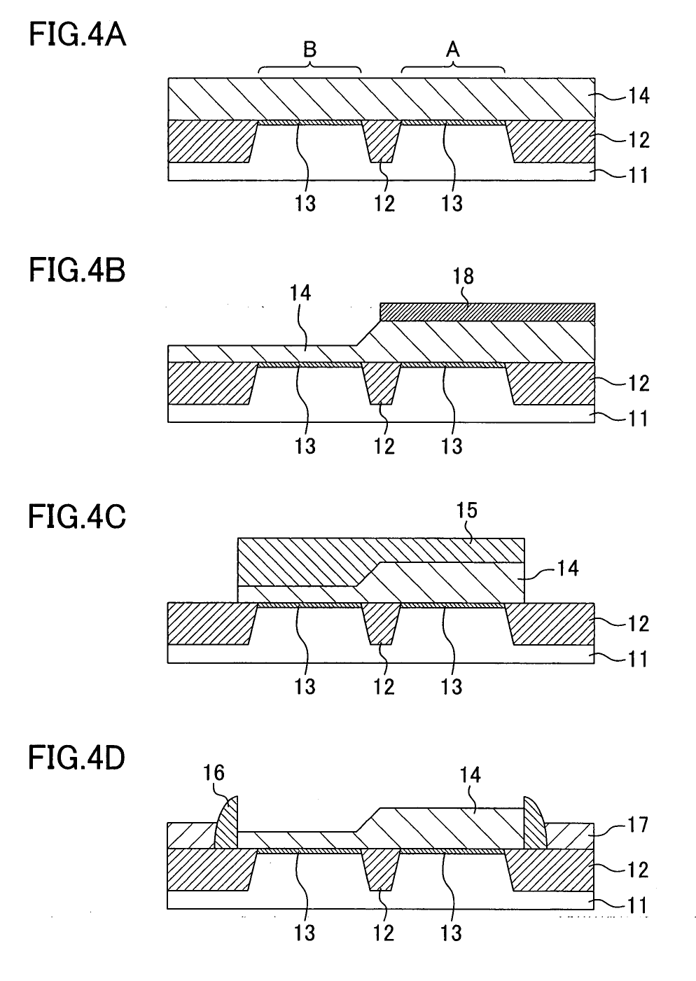

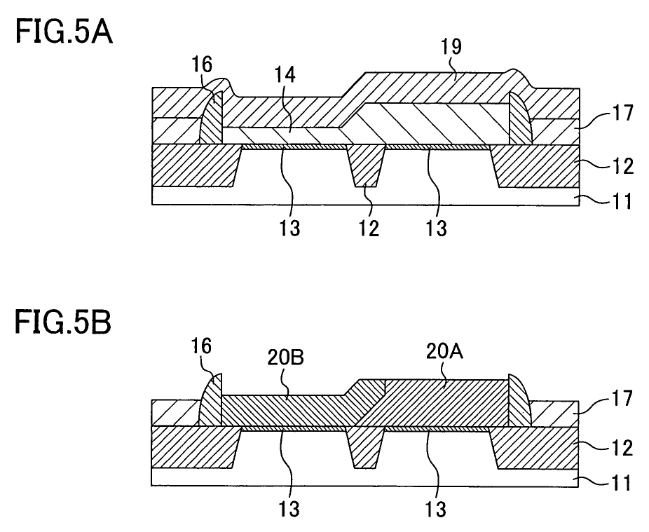

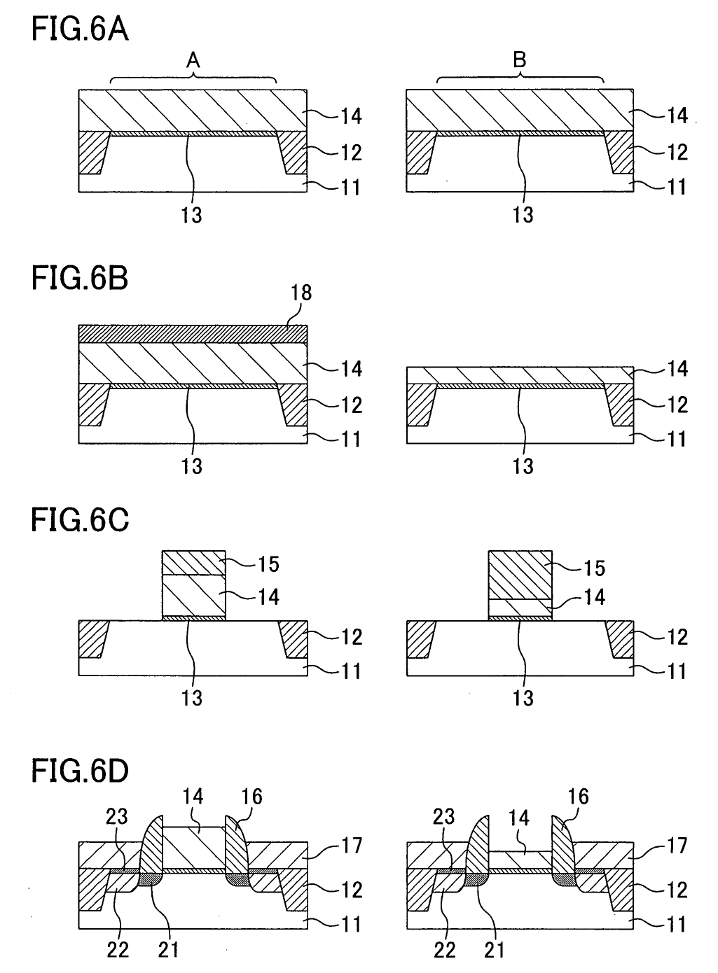

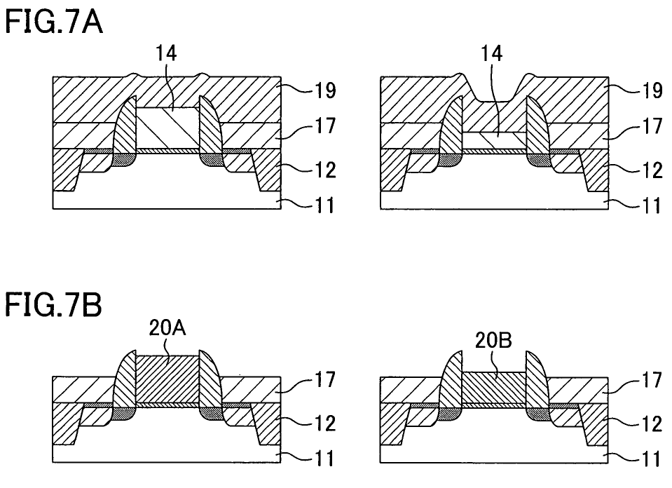

FIGS. 4A to 5B and FIGS. 6A to 7B are cross-sectional views schematically showing process steps of a method for fabricating a semiconductor device according to a second embodiment of the present invention, wherein FIGS. 4A to 5B are, like the first embodiment, cross-sectional views taken along the line II-II of FIG. 1 and showing process steps when viewed in a direction of the gate width and FIGS. 6A to 7B are cross-sectional views taken along the line IIIa-IIIa and the line IIIb-IIIb of FIG. 1 and showing process steps when viewed in a direction of the gate length.

The following description is given of the method for fabricating a semiconductor device according to this embodiment with reference to FIGS. 4A to 5B and FIGS. 6A to 7B. Out of the process steps of the fabrication method according to this embodiment, process steps common to those shown in FIGS. 2A to 2E and FIGS. 3A to 3E are not given in detail.

First, as shown in FIGS. 4A and 6A, an isolation region 12 is formed in a semiconductor substrate 11 of silicon to isolate an N-type MIS transistor forming region A (hereinafter, referred to as a region A) from a P-type MIS transistor forming region B (hereinafter, referred to as a region B). Thereafter, a gate insulating film 13 made of silicon dioxide or a hafnium oxide is formed on the semiconductor substrate 11 and a 100 nm thick polycrystalline silicon film 14 is then formed on the semiconductor substrate 11 (on the gate insulating film 13).

Next, as shown in FIGS. 4B and 6B, a resist film 18 is formed on the polycrystalline silicon film 14 to cover the region A and expose the region B. Thereafter, the exposed portion of the polycrystalline silicon film 14 is etched about a thickness of 60 nm using the resist film 18 as a mask to thin that portion of the polycrystalline silicon film 14 on the region B down to about 40 nm. The etching is performed, like the first embodiment, under a condition whereby the polycrystalline silicon film 14 after the end of the etching is formed with a stepped part having a tilted shoulder (forward tapered shoulder).

Next, as shown in FIGS. 4C and 6C, a silicon dioxide film 15 is formed with a thickness of 200 nm on the polycrystalline silicon film 14 and then planarized by CMP until it reaches a thickness of 60 nm on the region A. Thereafter, the silicon dioxide film 15, the polycrystalline silicon film 14 and the gate insulating film 13 are sequentially etched by photolithography or RIE to pattern the polycrystalline silicon film 14 into the shape of a gate electrode.

Next, as shown in FIGS. 4D and 6D, extension regions 21 and pocket regions (not shown) are formed in both the regions A and B of the semiconductor substrate 11, sidewalls 16 are then formed on the sides of the patterned polycrystalline silicon film 14 and source/drain regions 22 are then formed in both the regions A and B. Thereafter, the semiconductor substrate 11 is thermally treated to activate impurities implanted into the semiconductor substrate 11 and the polycrystalline silicon film 14 and only the top surfaces of the source/drain regions 22 of the semiconductor substrate 11 are silicided to form silicide regions 23. Subsequently, an interlayer film 17 of silicon dioxide is deposited on the layer stack, then thinned by CMP or RIE until exposure of the silicon dioxide film 15 and then completely removed by wet etching or RIE.

Next, as shown in FIGS. 5A and 7A, a Ni film 19 is deposited with a thickness of about 70 nm on the polycrystalline silicon film 14 and the semiconductor substrate 11 is thermally treated to induce silicidation reaction between the polycrystalline silicon film 14 and the Ni film 19.

Thereafter, an unreacted part of the Ni film 19 is selectively removed and the semiconductor substrate 11 is then additionally thermally treated. Thus, as shown in FIGS. 5B and 7B, a NiSi film 20A and a Ni₃Si film (or Ni₃₁Si₁₂ film) 20B are formed on the regions A and B, respectively. Like the first embodiment, the induction of the two-step silicidation reaction provides a fully silicided gate electrode structure. In this case, the first and second silicide regions 20A and 20B are formed so that the position of their interface at the bottom of their thickness can be on the isolation region 12 and near the region B and the position thereof at the top of their thickness can be directly above the isolation region 12 and near the region A or directly above the region A.

### Embodiment 3

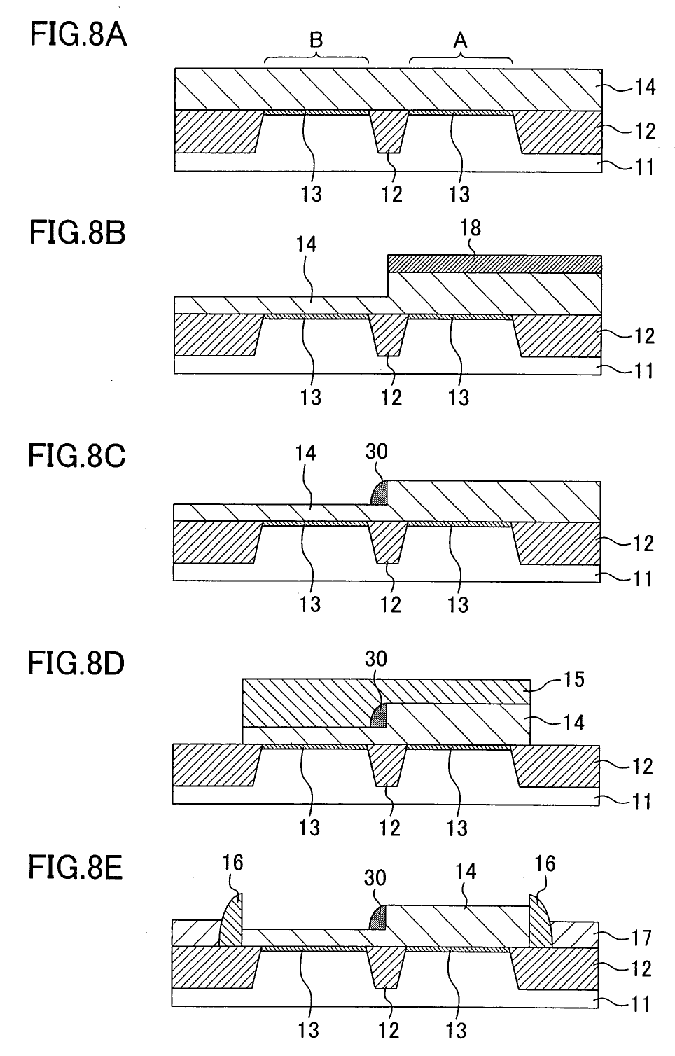

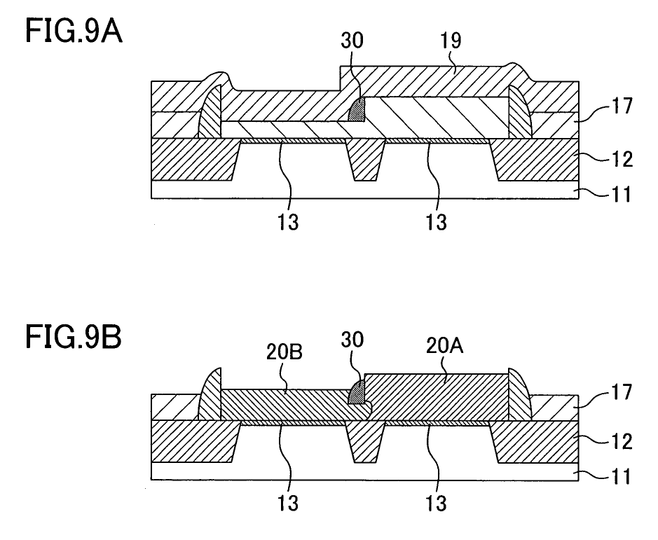

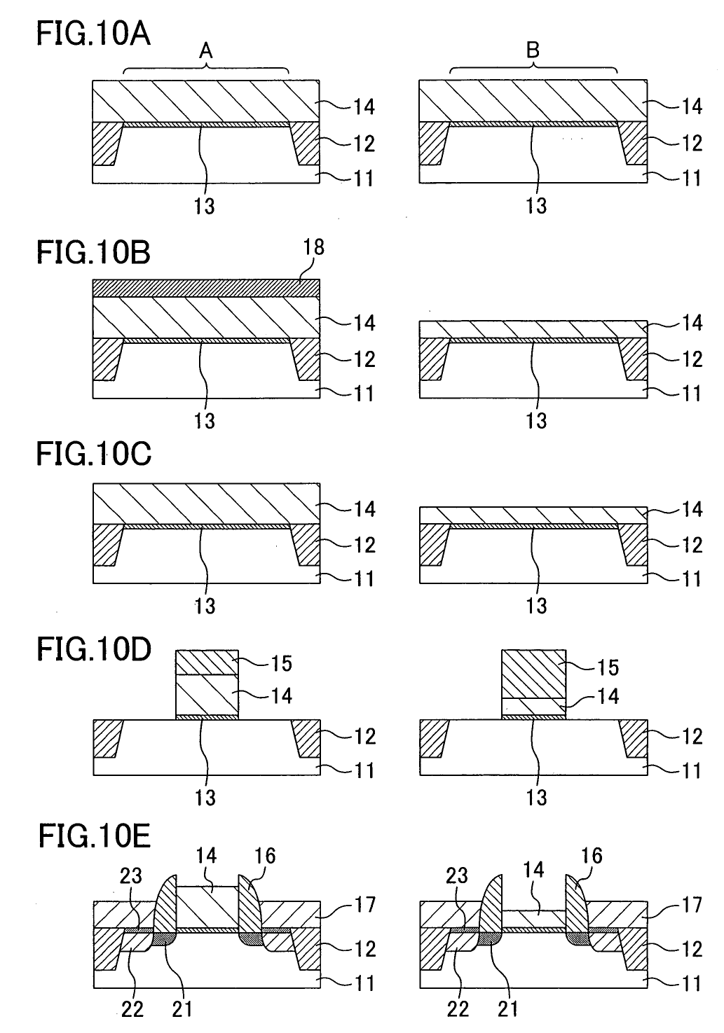

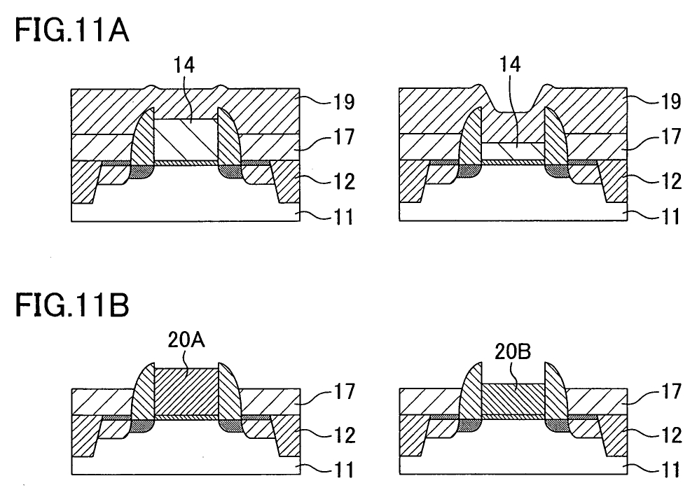

FIGS. 8A to 9B and FIGS. 10A to 11B are cross-sectional views schematically showing process steps of a method for fabricating a semiconductor device according to a third embodiment of the present invention, wherein FIGS. 8A to 9B are, like the first embodiment, cross-sectional views taken along the line II-II of FIG. 1 and showing process steps when viewed in a direction of the gate width and FIGS. 10A to 11B are cross-sectional views taken along the line IIIa-IIIa and the line IIIb-IIIb of FIG. 1 and showing process steps when viewed in a direction of the gate length.

The following description is given of the method for fabricating a semiconductor device according to this embodiment with reference to FIGS. 8A to 9B and FIGS. 10A to 11B. Out of the process steps of the fabrication method according to this embodiment, process steps common to those shown in FIGS. 2A to 2E and FIGS. 3A to 3E are not given in detail.

First, as shown in FIGS. 8A and 10A, an isolation region 12 is formed in a semiconductor substrate 11 of silicon to isolate an N-type MIS transistor forming region A (hereinafter, referred to as a region A) from a P-type MIS transistor forming region B (hereinafter, referred to as a region B). Thereafter, a gate insulating film 13 made of silicon dioxide or a hafnium oxide is formed on the semiconductor substrate 11 and a 100 nm thick polycrystalline silicon film 14 is then formed on the semiconductor substrate 11 (on the gate insulating film 13).

Next, as shown in FIGS. 8B and 10B, a resist film 18 is formed on the polycrystalline silicon film 14 to cover the region A and expose the region B. Thereafter, the exposed portion of the polycrystalline silicon film 14 is etched about a thickness of 60 nm using the resist film 18 as a mask to thin that portion of the polycrystalline silicon film 14 on the region B down to about 40 nm. The etching is implemented by anisotropic etching, so that the polycrystalline silicon film 14 after the end of the etching is formed with a stepped part having a substantially vertical shoulder.

Next, as shown in FIGS. 8C and 10C, a silicon nitride film is deposited with a thickness of 5 to 10 nm on the layer stack and then etched to form a sidewall 30 on the shoulder (side face) of the stepped part of the polycrystalline silicon film 14.

Next, as shown in FIGS. 8D and 10D, a silicon dioxide film 15 is formed with a thickness of 200 nm on the polycrystalline silicon film 14 and then planarized by CMP until it reaches a thickness of 60 nm on the region A. Thereafter, the silicon dioxide film 15, the sidewall 30, the polycrystalline silicon film 14 and the gate insulating film 13 are sequentially etched by photolithography or RIE to pattern the polycrystalline silicon film 14 into the shape of a gate electrode.

Next, as shown in FIGS. 8E and 10E, extension regions 21 and pocket regions (not shown) are formed in both the regions A and B of the semiconductor substrate 11, sidewalls 16 are then formed on the sides of the patterned polycrystalline silicon film 14 and source/drain regions 22 are then formed in both the regions A and B. Thereafter, the semiconductor substrate 11 is thermally treated to activate impurities implanted into the semiconductor substrate 11 and the polycrystalline silicon film 14 and only the top surfaces of the source/drain regions 22 of the semiconductor substrate 11 are silicided to form silicide regions 23. Subsequently, an interlayer film 17 of silicon dioxide is deposited on the layer stack, then thinned by CMP or RIE until exposure of the silicon dioxide film 15 and then completely removed by wet etching or RIE. In this case, the etching is performed so that the sidewall 30 is left.

Next, as shown in FIGS. 9A and 11A, a Ni film 19 is deposited with a thickness of about 70 nm on the polycrystalline silicon film 14 and the semiconductor substrate 11 is thermally treated to induce silicidation reaction between the polycrystalline silicon film 14 and the Ni film 19. Thereafter, an unreacted part of the Ni film 19 is selectively removed and the semiconductor substrate 11 is then additionally thermally treated. Thus, as shown in FIGS. 9B and 11B, a NiSi film 20A and a Ni₃Si film (or Ni₃₁Si₁₂ film) 20B are formed on the regions A and B, respectively. Like the first embodiment, the induction of the two-step silicidation reaction provides a fully silicided gate electrode structure. In this case, the first and second silicide regions 20A and 20B are formed so that the position of their interface at the bottom of their thickness can be on the isolation region 12.

The semiconductor device obtained by the above fabrication method includes a dual gate electrode 20 lying across the tops of both of a first element region (N-type MIS transistor region) 10A and a second element region (P-type MIS transistor region) 10B formed apart from each other with the isolation region 12 interposed therebetween. The dual gate electrode 20 is composed of two silicide regions with different compositions: a first silicide region (NiSi film) 20A on the first element region 10A and a second silicide region (Ni₃Si film or Ni₃₁Si₁₂ film) 20B on the second element region 10B. A sidewall 30 made of an insulating film is formed at part of the interface between the first and second silicide regions 20A and 20B.

According to this embodiment, in inducing silicidation reaction between the polycrystalline silicon film 14 and the Ni film 19 as shown in FIG. 9A, surplus metal supplied from the Ni film 19 laterally adjoining the stepped part of the polycrystalline silicon film 14 can be blocked by the sidewall 30 formed at the shoulder of the stepped part. Thus, the amount of offset of the interface between the silicide films 20A and 20B having different compositions can be reduced, which prevents variations in transistor characteristics due to offset of the interface.

Although the present invention has been so far described with reference to the preferred embodiments, their descriptions are not restrictive but can be modified into various forms. For example, although in the above embodiments a Ni film 19 is used as a metal film, the material used for the metal film is not particularly limited so long as it reacts with the polycrystalline silicon film 14 to form a metal silicide film. Examples of such material include high-melting point metals such as Co, Ti and Pt. Furthermore, the polycrystalline silicon film 14 may contain germanium.

What is claimed is:

1. A semiconductor device comprising:
a dual gate electrode lying across the tops of a first element region and a second element region formed apart from each other with an isolation region interposed between the first and second element regions;
said dual gate electrode being composed of a first silicide region and a second silicide region having different compositions, said first and second silicide region lying on top of the first and second element regions, respectively; and
the interface between the first and second silicide regions including a plane tilted from lower to higher positions in a direction of thickness of the dual gate electrode.

2. The semiconductor device of claim 1, wherein
the first and second silicide regions comprise regions formed by siliciding first and second regions of different thicknesses of a polycrystalline silicon film,
a stepped part of the polycrystalline silicon film between the first and second regions is formed to have a tilt, and
the position of the interface substantially corresponds to the position of the stepped part.

3. The semiconductor device of claim 1, wherein the position of the interface between the first and second silicide regions at the bottom of the dual gate electrode is on the isolation region.

4. The semiconductor device of claim 3, wherein the position of the interface at the bottom of the dual gate electrode is on the isolation region and closer to the second element region than the first element region.

5. The semiconductor device of claim 1, wherein the interface is tilted beginning with the bottom of the dual gate electrode and from near the second element region towards the first element region.

6. The semiconductor device of claim 1, wherein
the first element region is an N-type MIS transistor forming region,
the second element region is a P-type MIS transistor forming region,
the first silicide region is composed of a NiSi film, and
the second silicide region is composed of a Ni₃Si film or a Ni₃₁Si₁₂ film.

7. A method for fabricating a semiconductor device, comprising the steps of:
(a) forming a first element region and a second element region apart from each other with an isolation region interposed between the first and second element regions;
(b) forming a polycrystalline silicon film on the first and second element regions with a gate insulating film formed between the polycrystalline silicon film and both the first and second element regions;
(c) selectively etching the surface of the polycrystalline silicon film to form, in the polycrystalline silicon film, a first region on the first element region, a second region on the second element region and a boundary region between the first and second regions, said second region being thinner than said first region, said boundary region including a tilted shoulder;
(d) forming a metal film over the first region, the boundary region and the second region of the polycrystalline silicon film; and
(e) inducing silicidation reaction between the polycrystalline silicon film and the metal film to form a first silicide region and a second silicide region with different compositions, said first silicide region being formed by fully siliciding the first region of the polycrystalline silicon film, said second silicide region being formed by fully siliciding the second region of the polycrystalline silicon film,
wherein the step (e) includes fully siliciding the boundary region of the polycrystalline silicon film while forming the first and second silicide regions and the interface between the first and second silicide regions includes a plane tilted from lower to higher positions in a direction of thickness of the dual gate electrode.

8. The method of claim 7, wherein the first and second silicide regions forms a dual gate electrode lying across the tops of the first and second element regions.

9. The method of claim 7, further comprising the step (f) of patterning the polycrystalline silicon film into a gate electrode after the step (b) and before the step (c),
wherein the step (c) includes the steps of: (c1) forming a resist film on the patterned polycrystalline silicon film to cover the first element region and expose the second element region; and (c2) etching part of the polycrystalline silicon film located on the second element region with the resist film as a mask, thereby forming the second region of the polycrystalline silicon film and forming the tilted shoulder in the boundary region.

10. The method of claim 7, further comprising the step (f) of patterning the polycrystalline silicon film into a gate electrode after the step (c) and before the step (d),
wherein the step (c) includes the steps of: (c1) forming a resist film on the polycrystalline silicon film to cover the first element region and expose the second element region; and (c2) etching part of the polycrystalline silicon film located on the second element region with the resist film as a mask, thereby forming the second region of the polycrystalline silicon film and forming the tilted shoulder in the boundary region.

11. A method for fabricating a semiconductor device, comprising the steps of:
(a) forming a first element region and a second element region apart from each other with an isolation region interposed between the first and second element regions;
(b) forming a polycrystalline silicon film on the first and second element regions with a gate insulating film formed between the polycrystalline silicon film and both the first and second element regions;
(c) selectively etching the surface of the polycrystalline silicon film to form, in the polycrystalline silicon film, a first region on the first element region, a second region on the second element region and a boundary region between the first and second regions, said second region being thinner than said first region, said boundary region including a stepped part;
(d) forming an anti-silicidation film on the side face of the stepped part in the boundary region of the polycrystalline silicon film;
(e) patterning the polycrystalline silicon film into a gate electrode after the step (d);
(f) forming a metal film over the polycrystalline silicon film and the anti-silicidation film after the step (e); and
(g) inducing silicidation reaction between the polycrystalline silicon film and the metal film to form a first silicide region and a second silicide region with different compositions, said first silicide region being formed by fully siliciding the first region of the polycrystalline silicon film, said second silicide region being formed by fully siliciding the second region of the polycrystalline silicon film,
wherein the step (g) includes fully siliciding the boundary region of the polycrystalline silicon film with the anti-silicidation film as a mask while forming the first and second silicide regions.

12. The method of claim 11, wherein the first and second silicide regions forms a dual gate electrode lying across the tops of the first and second element regions.
